(19) United States
(12) Patent Application Publication
(10) Pub. No.: US 2025/0372558 A1
(43) Pub. Date: Dec. 4, 2025

(54) SEMICONDUCTOR MODULE AND MANUFACTURING METHOD

(71) Applicant: FUJI ELECTRIC CO., LTD., Kanagawa (JP)

(72) Inventors: Hideki IWATA, Hino-City (JP); Kou Tamada, Hino-City (JP); Masahiko TAKEI, Sagamihara-shi (JP); Eiji MOCHIZUKI, Matsumoto-city (JP); Kohei YAMAUCHI, Hachioji-City (JP); Yoshitaka NISHIMURA, Azumino-city (JP)

(21) Appl. No.: 19/218,340

(22) Filed: May 25, 2025

(30) Foreign Application Priority Data
Jun. 4, 2024 (JP) 2024-090990

(51) Int. Cl. H01L 23/00; H01L 21/48; H01L 23/498

(52) U.S. Cl. CPC H01L 24/14; H01L 21/4846; H01L 23/49833; H01L 23/49844; H01L 23/49866; H01L 23/562; H01L 24/13; H01L 24/16; H01L 24/81; H01L 24/32; H01L 24/73; H01L 2224/13017; H01L 2224/13082; H01L 2224/13083; H01L 2224/1403; H01L 2224/14132; H01L 2224/14134; H01L 2224/14152; H01L 2224/14154; H01L 2224/16227; H01L 2224/32225; H01L 2224/73253; H01L 2224/81191; H01L 2224/81193

(57) ABSTRACT

There is provided a semiconductor module including: a main electrode connection part which connects the main electrode of the semiconductor chip to the wiring substrate, in which the main electrode connection part has a first region which is provided with a plurality of first bonding portions, and a second region to which a distance from the first end side is greater than that to the first region, and which is provided with a plurality of second bonding portions, and a bonding strength per unit area by the plurality of first bonding portions is higher than the bonding strength per unit area by the plurality of second bonding portions.

The contents of the following patent application(s) are incorporated herein by reference:
NO. 2024-090990 filed in JP on Jun. 4, 2024.

### BACKGROUND

### 1. Technical Field

The present invention relates to a semiconductor module and a manufacturing method.

### 2. Related Art

There is known a technique for using a conductive bump to connect a semiconductor chip to a member such as a wiring substrate (for example, refer to Patent Documents 1 to 5).
Patent Document 1: Japanese Patent Application Publication No. 2008-227020
Patent Document 2: Japanese Patent Application Publication No. 2001-85558
Patent Document 3: Japanese Patent Application Publication No. H8-264540
Patent Document 4: Japanese Patent Application Publication No. 2000-174064
Patent Document 5: International Publication No. WO 2010/061428

### BRIEF DESCRIPTION OF THE DRAWINGS

FIG. 1 is a diagram describing an example of a semiconductor chip 100.

FIG. 2 is a diagram showing an example of a semiconductor module 200 according to an embodiment of the present invention.

FIG. 3 is a diagram showing an example of a manufacturing method for the semiconductor module 200 according to a reference example.

FIG. 4 is a diagram showing a configuration example of a main electrode connection part 150 and a gate connection part 160 according to an embodiment of the present invention.

FIG. 5 is a diagram showing another example of an arrangement of a gate bonding portion 161.

FIG. 6 is a diagram showing another configuration example of the main electrode connection part 150.

FIG. 7 is a diagram showing another configuration example of the main electrode connection part 150.

FIG. 8 is a diagram showing another configuration example of the main electrode connection part 150 and the gate connection part 160.

FIG. 9 is a diagram showing a first bonding portion 171, a second bonding portion 172, and a third bonding portion 173, in a cross section parallel to a connection direction.

FIG. 10 is a diagram showing examples of structures of the first bonding portion 171 and the second bonding portion 172.

FIG. 11 is a diagram showing other examples of the first bonding portion 171, the second bonding portion 172, and the third bonding portion 173.

FIG. 12 is a diagram showing an example of a manufacturing step for the semiconductor module 200 shown in FIG. 11.

FIG. 13 is a diagram showing a structure example of main wiring 120.

FIG. 14 is an enlarged cross-sectional view of a vicinity of an end side of a semiconductor substrate 10.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solution of the invention. In the present specification, the same parts in each figure are marked with the same reference numerals, and their description may be omitted. In addition, some configurations may not be illustrated for illustration purpose.

In the present specification, one side in a direction parallel to a depth direction of a semiconductor substrate is referred to as “upper” and another side is referred to as “lower”. One surface of two main surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using an orthogonal coordinate system of an X axis, a Y axis, and a Z axis. The orthogonal coordinate system merely specifies relative positions of components, and does not limit a specific direction. For example, a Z axis direction is not limited to indicating a height direction with respect to the ground. It should be noted that a +Z axis direction and a −Z axis direction are directions opposite to each other. If the Z axis direction is described without describing signs, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including an X axis direction and a Y axis direction.

A case where a term such as “same” or “equal” is used in the present specification may include a case where an error due to a variation in manufacturing or the like is included. The error is, for example, within 10%. In addition, in the present specification, the terms “parallel” or “perpendicular” may include an error of within 5°.

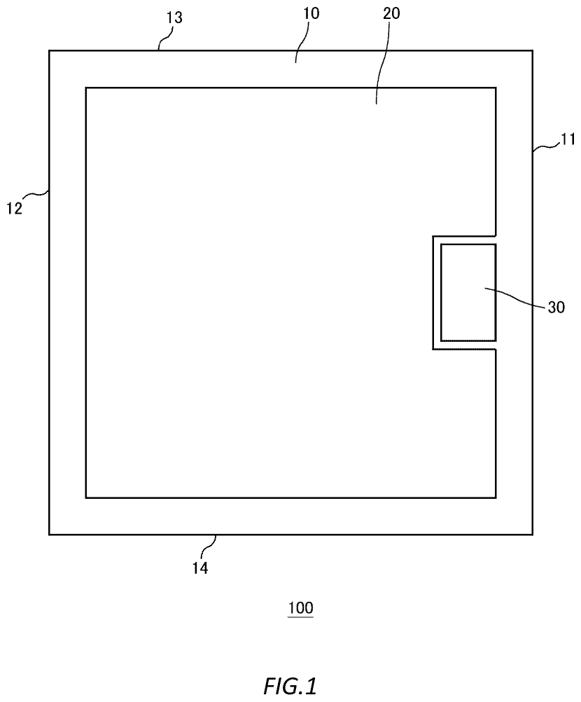

FIG. 1 is a diagram describing an example of a semiconductor chip 100. The semiconductor chip 100 of the present example is a chip provided with a power semiconductor element such as an IGBT (Insulated Gate Bipolar Transistor) or a MOSFET.

The semiconductor chip 100 has a semiconductor substrate 10. The semiconductor substrate 10 may be a silicon substrate, or may be a compound semiconductor substrate such as a silicon carbide substrate. In the semiconductor substrate 10, an emitter region of an N+ type, a collector region of a P+ type, a base region of a P-type, a drift region of an N-type, and the like of the IGBT are formed.

The semiconductor chip 100 has a gate pad 30 and a main electrode 20 which are provided on the same main surface. The main surface of the semiconductor chip 100 means two surfaces which have the greatest areas in the semiconductor chip 100. The two main surfaces are arranged opposite to each other. The gate pad 30 and the main electrode 20 are formed of a metal material such as Al or AlSi. Front surfaces of the gate pad 30 and the main electrode 20 may be covered with a plating layer of nickel, gold, or the like. In the present specification, the main surface on which the gate pad 30 and the main electrode 20 are provided may be referred to as a first main surface, and another main surface may be referred to as a second main surface.

The main electrode 20 is connected to a main terminal of a power semiconductor element provided on the semiconductor substrate 10. The main terminal of the power semiconductor element is a terminal through which a main current of the power semiconductor element flows. In a case of the IGBT, the emitter region or the collector region corresponds to the main terminal, and in a case of the MOSFET, a source region or a drain region corresponds to the main terminal. For example, the main electrode 20 is an emitter electrode in the IGBT, but is not limited to this. The present specification describes a case where the semiconductor chip 100 is the IGBT; however, in a case where the semiconductor chip 100 is the MOSFET, the “emitter” in the present specification may be read as the “source” and the “collector” as the “drain”.

A main electrode different from the main electrode 20 is provided on the semiconductor substrate 10. The main electrode is, for example, a collector electrode in the IGBT, but is not limited to this. The main electrode may be provided on a different main surface from that of the main electrode 20. In this case, the semiconductor chip 100 is a vertical device in which the main current flows in a thickness direction of the semiconductor substrate 10.

The gate pad 30 is connected to a gate electrode of the power semiconductor element provided on the semiconductor substrate 10. The gate electrode is arranged to face the base region of the power semiconductor element. A gate oxide film is provided between the gate electrode and the base region. When a predetermined ON voltage is applied to the gate electrode, a surface layer of the base region facing the gate electrode is inverted to a region of the N-type to form a channel. This causes the power semiconductor element to be in an ON state. The gate pad 30 is connected to the gate electrode provided in each region of the semiconductor substrate 10. The gate electrode may be an electrode of a trench type which is formed from a front surface to an inside of the semiconductor substrate 10.

FIG. 1 shows a plurality of end sides (a first end side 11, a second end side 12, a third end side 13, and a fourth end side 14) in an outer shape of the semiconductor chip 100 in a top view. The top view refers to a view from a direction perpendicular to the main surface of the semiconductor chip 100 or the semiconductor substrate 10. The outer shape of the semiconductor chip 100 may be an outer shape of the semiconductor substrate 10. In the semiconductor substrate 10 of the present example, the first end side 11 and the second end side 12 are parallel to each other, the third end side 13 and the fourth end side 14 are parallel to each other, and the first end side 11 and the third end side 13 are perpendicular to each other.

The first end side 11 of the present example is an end side that is closest to the gate pad 30, among the plurality of end sides. The second end side 12 is an end side that is farthest away from the first end side 11, among the plurality of end sides of the semiconductor chip 100. The third end side 13 and the fourth end side 14 are end sides each of which connects the first end side 11 and the second end side 12.

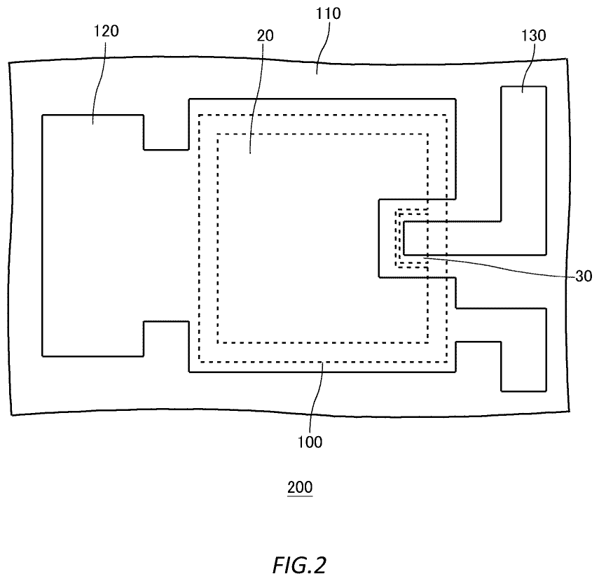

FIG. 2 is a diagram showing an example of a semiconductor module 200 according to an embodiment of the present invention. FIG. 2 shows an enlarged view of a part of the semiconductor module 200. The semiconductor module 200 includes the semiconductor chip 100 and a wiring substrate 110. The wiring substrate 110 has a base material formed of an insulation material, main wiring 120, and a gate runner 130. The main wiring 120 and the gate runner 130 are wiring formed of a metal material such as copper, on the base material. Front surfaces of the main wiring 120 and the gate runner 130 may be covered with plating layers of nickel, gold, or the like.

The semiconductor chip 100 is fixed to the wiring substrate 110. In FIG. 2, the semiconductor chip 100 fixed to the wiring substrate 110 is indicated by a dashed line. The main electrode 20 of the semiconductor chip 100 is connected to the main wiring 120. The gate pad 30 is connected to the gate runner 130.

The semiconductor module 200 may have a housing which houses the semiconductor chip 100 and the wiring substrate 110. A space of the housing which houses the semiconductor chip 100 and the wiring substrate 110 may be sealed with an insulation material such as gel or epoxy resin.

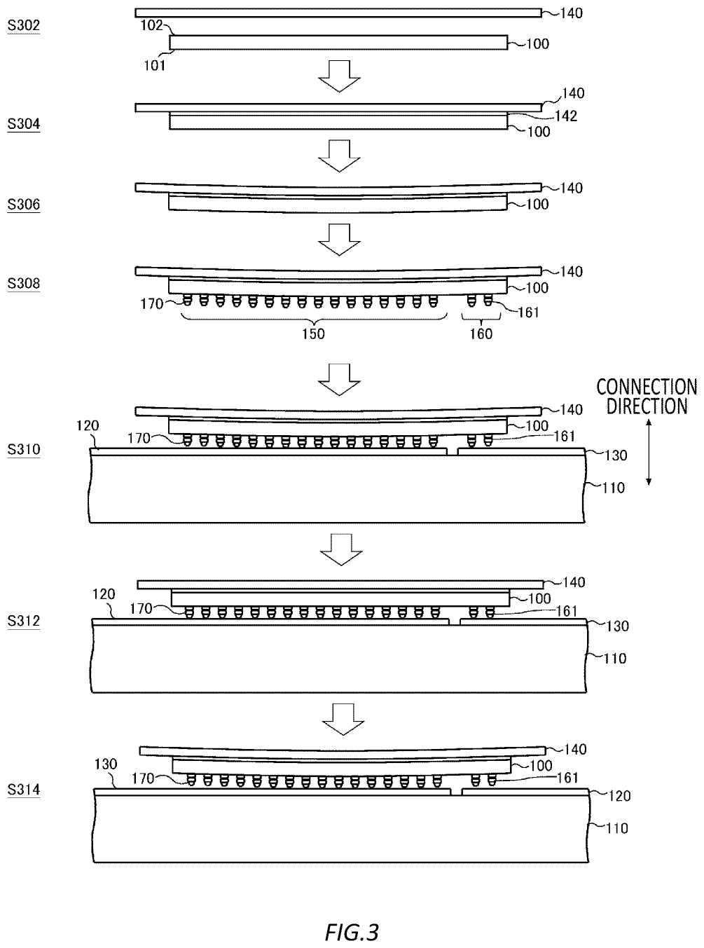

FIG. 3 is a diagram showing an example of a manufacturing method for the semiconductor module 200 according to a reference example. First, in a preparation step S302, the semiconductor chip 100 and main wiring 140 are prepared. The main wiring 140 is wiring different from the main wiring 120 shown in FIG. 2. For example, the main wiring 140 is wiring of a lead frame or the like of a plate shape. The main wiring 140 may be formed of a metal material such as copper.

In step S304, the main wiring 140 is connected to a main electrode provided on a second main surface 102 of the semiconductor chip 100. The main electrode of the present example is provided over the entire second main surface 102. The main wiring 140 may be connected to the main electrode to cover the entire main electrode. The main wiring 140 may be connected to the main electrode of the semiconductor chip 100 by a connection portion 142 of solder or the like. As an example, the semiconductor chip 100 is heated to approximately 200° C. at a time of being bonded to the main wiring 140. In each figure, a reference sign and numeral of the connection portion 142 may be omitted.

In step S306, after the semiconductor chip 100 and the main wiring 140 are bonded to each other, the heating of the semiconductor chip 100 is stopped and a temperature of the semiconductor chip 100 is lowered to approximately room temperature (for example, 25° C.). In step S306, the semiconductor chip 100 and the main wiring 140 may be warped due to a difference in a linear expansion coefficient between the semiconductor chip 100 and the main wiring 140. For example, as shown in FIG. 3, the semiconductor chip 100 and the main wiring 140 are warped to protrude toward a semiconductor chip 100 side. As an example, a warp of 30 μm or more in a height direction may occur between the center and an end portion of the semiconductor chip 100.

In step S308, a main electrode connection part 150 and a gate connection part 160 are formed. The main electrode connection part 150 connects the main electrode 20 of the semiconductor chip 100 to the main wiring 120 of the wiring substrate 110. The main electrode connection part 150 has a plurality of main electrode bonding portions 170. The gate connection part 160 connects the gate pad 30 to the gate runner 130 of the wiring substrate 110. The gate connection part 160 has a plurality of gate bonding portions 161. The main electrode bonding portion 170 and the gate bonding portion 161 are bumps formed of a conductive material such as gold or copper. The main electrode bonding portion 170 and the gate bonding portion 161 may be formed of a conductive material to have a spherical shape, may be formed of a conductive material to have a pillar shape, or may have another shape. The plurality of main electrode bonding portions 170 are arranged to be distributed over the entire main electrode 20. The plurality of gate bonding portions 161 are arranged to be distributed over the entire gate pad 30.

In the example of FIG. 3, the main electrode bonding portion 170 and the gate bonding portion 161 are formed on a first main surface 101 of the semiconductor chip 100. In another example, the main electrode bonding portion 170 and the gate bonding portion 161 may be formed on the wiring substrate 110, or may be formed on both of the semiconductor chip 100 and the wiring substrate 110.

In step S310, the semiconductor chip 100 is placed on the wiring substrate 110 via the main electrode bonding portion 170 and the gate bonding portion 161. In step S312, the entire surface of the semiconductor chip 100 is pressed to a direction of the wiring substrate 110 while the semiconductor chip 100 and the wiring substrate 110 are heated. In this manner, the semiconductor chip 100 is fixed to the wiring substrate 110 in a flattened state, which makes it possible to manufacture the semiconductor module 200. In the present specification, a direction in which the semiconductor chip 100 is connected to the wiring substrate 110 may be referred to as a connection direction. The connection direction is a normal direction perpendicular to the first main surface 101 of the semiconductor chip 100. When the first main surface 101 is warped, the normal direction at the center of the first main surface 101 may be set as the connection direction. Alternatively, the normal direction of an upper surface of the main wiring 120 may be set as the connection direction.

Step S314 shows a state in which the temperature of the semiconductor chip 100 is lowered to approximately room temperature after the semiconductor module 200 is manufactured. When the temperature of the semiconductor chip 100 is lowered, as in step S306, stress is generated in the direction in which the semiconductor chip 100 is warped, according to the difference in the linear expansion coefficient between the semiconductor chip 100 and the main wiring 140. As a result, as shown in FIG. 3, in parts of the main electrode bonding portion 170 and the gate bonding portion 161, a breakage may occur. Due to the breakage, it is not possible to maintain an electrical connection between the semiconductor chip 100 or the wiring substrate 110, and the main electrode bonding portion 170 or the gate bonding portion 161.

The closer to the end portion of the semiconductor chip 100, the greater an amount of the warp of the semiconductor chip 100. For this reason, the closer the bonding portion is to the end portion of the semiconductor chip 100, the more likely it is that the breakage occurs. In addition, in a vicinity of the gate pad 30, the number of the bonding portions tends to be small. A semiconductor element such as the IGBT is formed in an active region overlapping with the main electrode 20. In order to increase an area of the active region, an area of the gate pad 30 tends to become small. For this reason, it is difficult to increase the number of the gate bonding portions 161 which are provided on the gate pad 30. In addition, different potentials are applied to the gate pad 30 and the main electrode 20, and thus they are arranged to be spaced apart from each other. Between the gate pad 30 and the main electrode, a protective layer of polyimide or the like is formed. It is not possible to provide the bonding portion on the protective layer, and thus the number of the bonding portions around a periphery of the gate pad 30 is small. Therefore, the number of the bonding portions is small, particularly in the vicinity of the gate pad 30, and it is more likely that the breakage occurs.

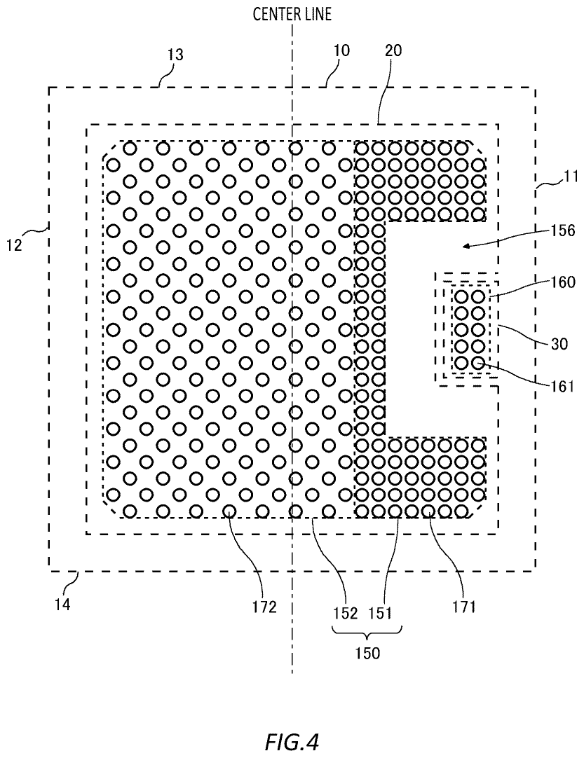

FIG. 4 is a diagram showing a configuration example of the main electrode connection part 150 and the gate connection part 160 according to an embodiment of the present invention. The structure other than the main electrode connection part 150 and the gate connection part 160 is similar to those of the examples described with reference to FIG. 1 to FIG. 3. In FIG. 4, the semiconductor substrate 10, the main electrodes 20, and the gate pad 30 in the semiconductor chip 100 are indicated by the dashed line. As described above, the main electrode connection part 150 has the plurality of main electrode bonding portions 170 at positions overlapping with the main electrode 20. As the plurality of main electrode bonding portions 170, the example of FIG. 4 shows a plurality of first bonding portions 171 and a plurality of second bonding portions 172. In addition, the gate connection part 160 has the plurality of gate bonding portions 161 at positions overlapping with the gate pad 30. FIG. 4 schematically shows the first bonding portion 171, the second bonding portion 172, and the gate bonding portion 161 by circles. A shape of each bonding portion in the top view may be circular, but is not limited to being circular.

On an arrangement surface parallel to the first main surface 101 of the semiconductor chip 100, the main electrode connection part 150 has a first region 151 and a second region 152. The first region 151 is provided with the plurality of first bonding portions 171. The second region 152 is provided with a plurality of second bonding portions 172. The first bonding portion 171 and the second bonding portion 172 may be formed of the same material, or may be formed of materials different from each other. The first bonding portion 171 and the second bonding portion 172 may have the same shape, or may have shapes different from each other. On the arrangement surface parallel to the first main surface 101, the first bonding portion 171 and the second bonding portion 172 may have the same size (that is, an area), or may have sizes different from each other.

A distance from the first end side 11 to the second region 152 is greater than that to the first region 151. That is, in a direction perpendicular to the first end side 11, the first region 151 is arranged between the second region 152 and the first end side 11. As shown in FIG. 4, a boundary between the first region 151 and the second region 152 may be a straight line parallel to the first end side 11. In the main electrode connection part 150 in which the main electrode bonding portion 170 is provided, the entire part facing the first end side 11 may be the first region 151.

In the present example, on the arrangement surface parallel to the first main surface 101, a bonding strength per unit area by the first bonding portion 171 is higher than the bonding strength per unit area by the second bonding portion 172. The bonding strength refers to a strength at which it is possible to maintain the electrical connection between the semiconductor chip 100 and the wiring substrate 110. The bonding strength may be indicated by a magnitude of stress in the connection direction. In other words, the bonding strength may be an upper limit value of the stress in the connection direction at which it is possible to maintain the electrical connection between the semiconductor chip 100 and the wiring substrate 110. The bonding strength may be indicated by an amount of warp of the semiconductor chip 100 measured at room temperature (25° C.), in a state in which the semiconductor chip 100 is removed from the wiring substrate 110. In other words, the bonding strength may be an upper limit value of the amount of warp of the semiconductor chip 100 at which it is possible to maintain the electrical connection between the semiconductor chip 100 and the wiring substrate 110. The bonding strength may be a lower one, between a connection strength at which it is possible to maintain the connection of each bonding portion between the semiconductor chip 100 and the wiring substrate 110; and a breaking strength at which the breakage of the bonding portion itself does not occur.

By causing the bonding strength per unit area by the first bonding portion 171 to be higher than the bonding strength per unit area of the second bonding portion 172, it is possible to suppress an occurrence of the breakage or the like in the first region 151. This makes it possible to suppress the occurrence of the breakage or the like in the vicinity of the gate pad 30 in which the breakage or the like is comparatively likely to occur.

In the example of FIG. 4, the number of the first bonding portions 171 per unit area is greater than the number of the second bonding portions 172 per unit area. In other words, a density (for example, the total number of the first bonding portions 171 in the first region 151/the area of the first region 151) at which the first bonding portions 171 are provided is higher than the density (for example, the total number of the second bonding portions 172 in the second region 152/the area of the second region 152) at which the second bonding portions 172 are provided.

The density of the first bonding portion 171 may be 1.2 times or more, may be 1.5 times or more, or may be two times or more of that of the second bonding portion 172. In the example of FIG. 4, the density of the first bonding portions 171 is two times the density of the second bonding portions 172. In the example of FIG. 4, a plurality of second bonding portion 172 are arranged in the second region 152 in a predetermined repeating pattern. The plurality of first bonding portions 171 may include ones arranged in the same repeating pattern as that of the second bonding portions 172, and ones arranged additionally.

In the example of FIG. 4, the bonding strength per unit area by the gate bonding portion 161 is the same as the bonding strength per unit area by the first bonding portion 171. The number of the first bonding portions 171 per unit area may be the same as the number of the gate bonding portions 161 per unit area. An arrangement interval between the first bonding portions 171 may be the same as an arrangement interval between the gate bonding portions 161.

In the example of FIG. 4, the second region 152 is provided up to a position that is closest to the second end side 12 in the main electrode connection part 150. In the present example, in the main electrode connection part 150, the entire part that is closer to the second end side 12 than the first region 151 is the second region 152. In the second region 152, the second bonding portions 172 are arranged at a comparatively low density. Therefore, a sealant such as gel or epoxy resin is likely to enter between the second bonding portions 172, which makes it easy to seal the semiconductor chip 100 and the wiring substrate 110. The second bonding portions 172 may be uniformly arranged in the second region 152. In other words, the plurality of second bonding portions 172 may be arranged in the second region 152 at equal intervals.

The first bonding portions 171 may be uniformly arranged in the first region 151. In another example, the first region 151 may have a part in which the first bonding portions 171 have densities different from each other. The density of the first bonding portion 171 in any part may be higher than the density of the second bonding portion 172. By providing a part in which the density of the first bonding portion 171 is comparatively low, the sealant is likely to enter into that part.

The first main surface 101 of the semiconductor chip 100 is virtually divided into two equal parts by a center line parallel to the first end side 11. The number of the bonding portions provided in the two equally divided regions (in the present example, the number of the first bonding portions 171, and the second bonding portions 172, and the gate bonding portions 161) may be the same as each other. This makes it possible to reinforce the bonding strength in the vicinity of the gate pad 30, and keep a balance of the bonding strength between the two regions. The number of the bonding portions provided in the two regions may be different from each other. The number of the bonding portions provided in the two regions may have a difference from each other within ±5%, or may also have a difference from each other within ±10%. In this case, as well, it is possible to reinforce the bonding strength in the vicinity of the gate pad 30, and keep a balance of the bonding strength between the two regions.

The first region 151 may have a recess portion 156 which is recessed in the direction perpendicular to the first end side 11 on the arrangement surface. The recess portion 156 of the present example is rectangular; however, a shape of the recess portion 156 is not limited to this. The first bonding portion 171 is not arranged in the recess portion 156.

The gate pad 30 may be arranged to face the recess portion 156 in the direction perpendicular to the first end side 11. In this case, the gate connection part 160 is also arranged to face the recess portion 156 in the direction perpendicular to the first end side 11. At least a part of the gate pad 30 may be arranged in the recess portion 156. The entire gate pad 30 may be arranged in the recess portion 156. Similarly, at least a part or the entirety of the gate connection part 160 may be arranged in the recess portion 156.

In the recess portion 156 between the gate connection part 160 and the first region 151, neither the first bonding portion 171 nor the gate bonding portion 161 is arranged. A width of the gate connection part 160 may be greater than a distance between the second bonding portions 172. In other words, the shortest distance between the gate bonding portion 161 and the first bonding portion 171 may be greater than an interval between the second bonding portions 172.

In the example of FIG. 4, the density of the first bonding portions 171 is set to be high, thereby increasing the bonding strength in the first region 151. In another example, a material of the first bonding portion 171 may be caused to be different from a material of the second bonding portion 172, thereby increasing the bonding strength in the first region 151. For example, the first bonding portion 171 may be formed of a material having a higher hardness than that of the second bonding portion 172. Alternatively, the first bonding portion 171 may be formed of a material which has higher connectivity to the main electrode 20 or the main wiring 120 than that of the second bonding portion 172. In addition, on the arrangement surface, a cross-sectional area of the first bonding portion 171 may be set to be greater than a cross-sectional area of the second bonding portion 172, thereby increasing the bonding strength in the first region 151. Among the number of the first bonding portions 171 per unit area, the material, and the cross-sectional area, one or more parameters may be adjusted, thereby increasing the bonding strength in the first region 151.

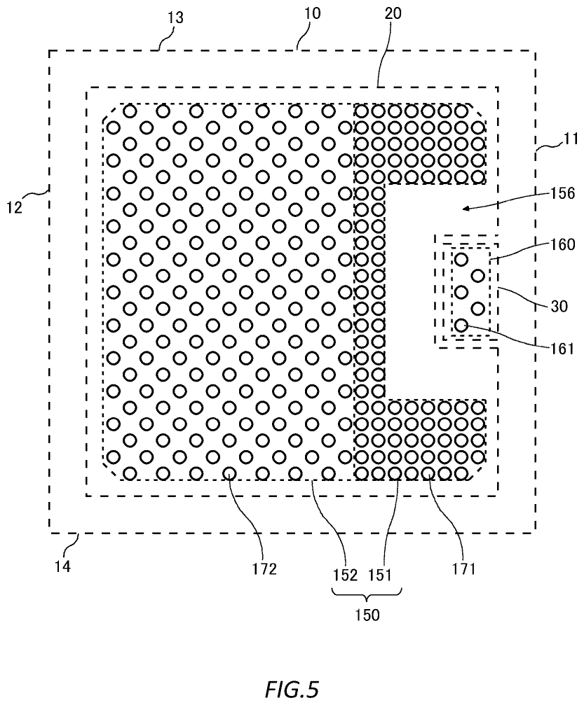

FIG. 5 is a diagram showing another example of an arrangement of the gate bonding portion 161. A structure other than the gate bonding portion 161 is similar to that of any of the examples in the present specification. In the present example, the bonding strength per unit area by the gate bonding portion 161 is smaller than the bonding strength per unit area by the first bonding portion 171. The bonding strength by the gate bonding portion 161 may be the same as, or may be different from the bonding strength by the first bonding portion 171.

In the example of FIG. 5, the number of the gate bonding portions 161 per unit area is smaller than the number of the first bonding portions 171 per unit area. In other words, the density (for example, the total number of the gate bonding portions 161 in the gate connection part 160/the area of the gate connection part 160) at which the gate bonding portions 161 are provided is lower than the density at which the first bonding portions 171 are provided. With the present example, by providing the first region 151 around the gate pad 30, it is possible to reinforce the bonding strength in the vicinity of the gate pad 30, and easily seal the vicinity of the gate pad 30.

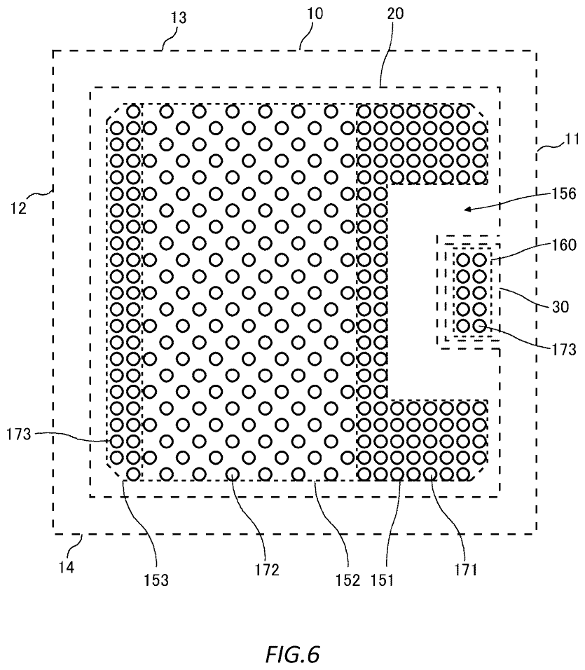

FIG. 6 is a diagram showing another configuration example of the main electrode connection part 150. A structure other than the main electrode connection part 150 is similar to that of any of the examples in the present specification. On the arrangement surface parallel to the first main surface 101, the main electrode connection part 150 of the present example has the first region 151, the second region 152, and a third region 153.

The third region 153 is a region to which the distance from the second end side 12 is smaller than that to the second region 152. That is, in a direction perpendicular to the second end side 12, the third region 153 is arranged between the second region 152 and the second end side 12. As shown in FIG. 6, a boundary between the second region 152 and the third region 153 may be a straight line parallel to the second end side 12. In the main electrode connection part 150 in which the main electrode bonding portion 170 is provided, the entire part facing the second end side 12 may be the third region 153.

The third region 153 has a plurality of third bonding portions 173. In the present example, the bonding strength per unit area by the third bonding portion 173 is higher than the bonding strength per unit area by the second bonding portion 172. Similar to the first bonding portion 171, by adjusting at least one parameter of the density, the material, or the cross-sectional area of the third bonding portion 173, it is possible to adjust the bonding strength by the third bonding portion 173. For example, the density of the third bonding portion 173 may be higher than the density of the second bonding portion 172.

The bonding strength per unit area by the third bonding portion 173 may be the same as, or may be different from the bonding strength per unit area by the first bonding portion 171. For example, the bonding strength per unit area by the third bonding portion 173 may be lower than the bonding strength per unit area by the first bonding portion 171.

The area of the third region 153 may be smaller than the area of the first region 151. In the vicinity of the second end side 12, there is not provided a region, such as the recess portion 156, which has no bonding portion. Therefore, it is possible to reinforce the bonding strength in the third region 153 which is comparatively small.

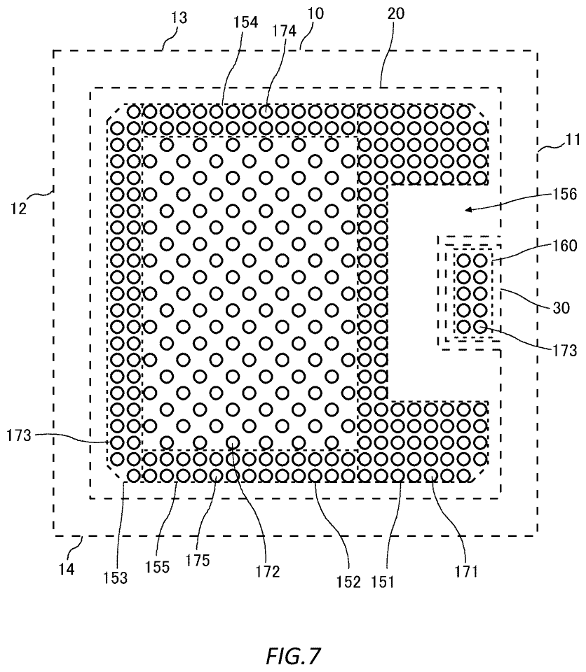

FIG. 7 is a diagram showing another configuration example of the main electrode connection part 150. A structure other than the main electrode connection part 150 is similar to that of any of the examples in the present specification. On the arrangement surface parallel to the first main surface 101, the main electrode connection part 150 of the present example has the first region 151, the second region 152, the third region 153, a fourth region 154, and a fifth region 155.

The fourth region 154 is a region to which the distance from the third end side 13 is smaller than that to the second region 152. That is, in a direction perpendicular to the third end side 13, the fourth region 154 is arranged between the second region 152 and the third end side 13. As shown in FIG. 7, a boundary between the second region 152 and the fourth region 154 may be a straight line parallel to the third end side 13.

The fourth region 154 has a plurality of fourth bonding portions 174. In the present example, the bonding strength per unit area by the fourth bonding portion 174 is higher than the bonding strength per unit area by the second bonding portion 172. Similar to the first bonding portion 171, by adjusting at least one parameter of the density, the material, or the cross-sectional area of the fourth bonding portion 174, it is possible to adjust the bonding strength by the fourth bonding portion 174. For example, the density of the fourth bonding portion 174 may be higher than the density of the second bonding portion 172.

The fifth region 155 is a region to which the distance from the fourth end side 14 is smaller than that to the second region 152. That is, in a direction perpendicular to the fourth end side 14, the fifth region 155 is arranged between the second region 152 and the fourth end side 14. As shown in FIG. 7, a boundary between the second region 152 and the fifth region 155 may be a straight line parallel to the fourth end side 14. The second region 152 of the present example is surrounded by the first region 151, the third region 153, the fourth region 154, and the fifth region 155.

The fifth region 155 has a plurality of fifth bonding portions 175. In the present example, the bonding strength per unit area by the fifth bonding portion 175 is higher than the bonding strength per unit area by the second bonding portion 172. Similar to the first bonding portion 171, by adjusting at least one parameter of the density, the material, or the cross-sectional area of the fifth bonding portion 175, it is possible to adjust the bonding strength by the fifth bonding portion 175. For example, the density of the fifth bonding portion 175 may be higher than the density of the second bonding portion 172.

The bonding strengths per unit area by the fourth bonding portion 174 and the fifth bonding portion 175 may be the same as, or may be different from the bonding strength per unit area by the first bonding portion 171. For example, the bonding strengths per unit area by the fourth bonding portion 174 and the fifth bonding portion 175 may be lower than the bonding strength per unit area by the first bonding portion 171.

The area of the fourth region 154 may be smaller than the area of the first region 151. The area of the fifth region 155 may be smaller than the area of the first region 151.

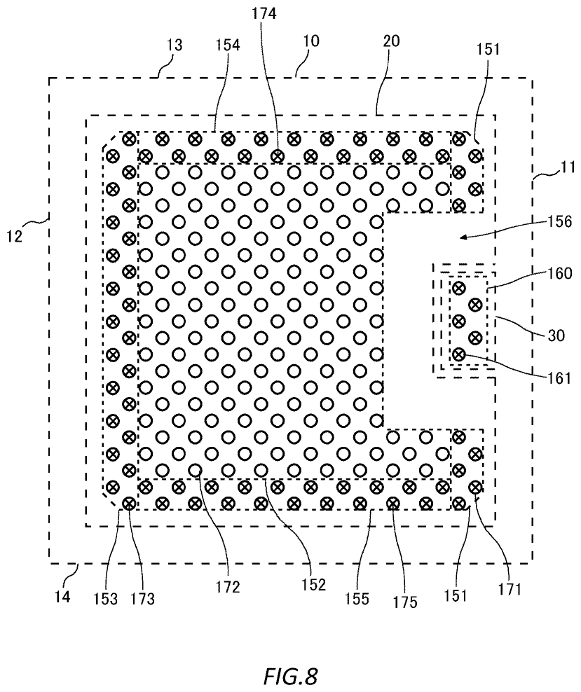

FIG. 8 is a diagram showing another configuration example of the main electrode connection part 150 and the gate connection part 160. In FIG. 8, the main electrode connection part 150 of the present example has the first region 151, the second region 152, the third region 153, the fourth region 154, and the fifth region 155. The main electrode connection part 150 may not have any one or more of regions of the third region 153, the fourth region 154, and the fifth region 155 as in any of the examples shown in FIG. 4 to FIG. 7.

In the present example, at least one first bonding portion 171 is longer than any of the second bonding portions 172 in the connection direction. All of the second bonding portions 172 may have the same length. All of the first bonding portions 171 may be longer than the second bonding portion 172 in the connection direction. All of the first bonding portions 171 may have the same length.

In FIG. 8, the bonding portion that is longer than the second bonding portion 172 is marked with a cross. By lengthening the first bonding portion 171, it is possible to reinforce the bonding strength in the first region 151, even when the semiconductor chip 100 is warped. In addition, it is possible to connect the semiconductor chip 100 in a state of being warped, to the wiring substrate 110. As described in step S312 of FIG. 3, the semiconductor chip 100 may not be in a flattened state to be connected to the wiring substrate 110, and thus no stress is generated in the first region 151 even when the temperature of the semiconductor chip 100 becomes approximately room temperature. Therefore, it is possible to reinforce the bonding strength in the first region 151.

The third bonding portion 173, the fourth bonding portion 174, and the fifth bonding portion 175 may also be longer than the second bonding portion 172. In addition, the gate bonding portion 161 may also be longer than the second bonding portion 172. That is, the long bonding portions may be arranged along the end sides of the semiconductor chip 100. This makes it possible to reinforce the bonding strengths of the first region 151, the third region 153, the fourth region 154, the fifth region 155, and the gate connection part 160, in the vicinity of the end side of the semiconductor chip 100 where an amount of warp is great. The first region 151 of the present example is not provided between the gate connection part 160 and the second region 152; however, the first region 151 may also be provided between the gate connection part 160 and the second region 152, as in the example of FIG. 4 or the like.

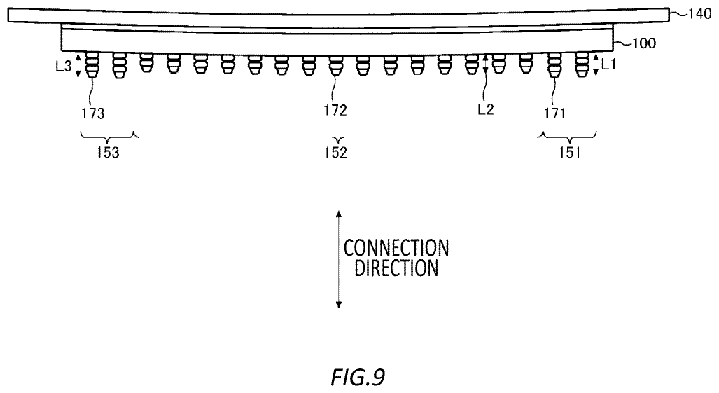

FIG. 9 is a diagram showing the first bonding portion 171, the second bonding portion 172, and the third bonding portion 173, in a cross section parallel to a connection direction. The length of the first bonding portion 171 in the connection direction is set as L1, the length of the second bonding portion 172 is set as L2, and the length of the third bonding portion 173 is set as L3. As described above, the length L1 is greater than the length L2. The length L1 may be 10 μm or more longer than the length L2, may be 20 μm or more longer, or may be 30 μm or more longer. It is preferable that the difference between the length L1 and the length L2 is determined according to an amount of warp of the semiconductor substrate 10. The length L3 may be the same as the length L1. Although not shown in FIG. 9, the lengths of the fourth bonding portion 174, the fifth bonding portion 175, and the gate bonding portion 161 may also be the same as the length L1 of the first bonding portion 171.

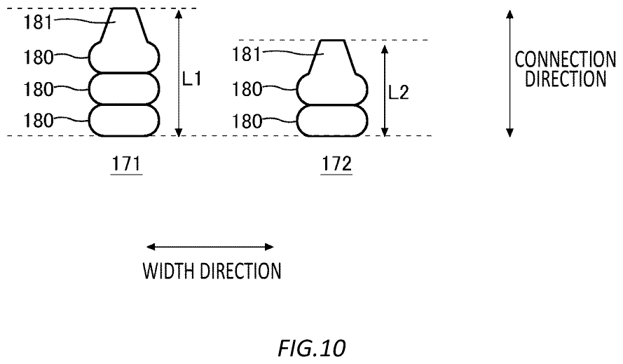

FIG. 10 is a diagram showing examples of structures of the first bonding portion 171 and the second bonding portion 172. The third bonding portion 173, the fourth bonding portion 174, the fifth bonding portion 175, and the gate bonding portion 161 may have structures similar to that of the first bonding portion 171.

In FIG. 10, a direction perpendicular to the connection direction is set as a width direction. In the first bonding portion 171 and the second bonding portion 172, one or more bumps 180 are stacked in the connection direction. Each bump 180 may have a protruding part that protrudes outward in the width direction. A part where the two bumps 180 are connected is recessed inward, in the width direction, from the protruding part of the bump 180. The bump 180 arranged at either end portion in the connection direction may have a contact portion 181. The contact portion 181 may have a tapered shape in which the farther away from a stacked part of the bump 180 in the connection direction, the smaller a cross-sectional area. In another example, the contact portion 181 may not be provided.

In the present example, the number of stages of the bumps 180 in at least one first bonding portion 171 is greater than the number of stages of the bumps 180 in any of the second bonding portions 172. All of the second bonding portions 172 may have the same number of stages of the bumps 180. All of the first bonding portions 171 may have a greater number of stages of the bumps 180 than that of the second bonding portions 172. All of the first bonding portions 171 may have the same number of stages of the bumps 180.

In a manufacturing step of the semiconductor module 200, the plurality of bumps 180 stacked in the first bonding portion 171 may be provided on either the semiconductor chip 100 or the wiring substrate 110. In another example, among the plurality of bumps 180 which are stacked in the first bonding portion 171, some may be provided on the semiconductor chip 100 and the remaining some may be provided on the wiring substrate 110. In this case, the semiconductor chip 100 and the wiring substrate 110 are arranged such that the bumps 180 on the semiconductor chip 100 side and the bumps 180 on a wiring substrate 110 side are stacked. For example, each of the bumps 180 of the second bonding portion 172 may be provided on the semiconductor chip 100 (or the wiring substrate 110). In addition, among the plurality of bumps 180 of the first bonding portion 171, the same number of the bumps 180 as that of the second bonding portion 172 may be provided on the semiconductor chip 100 (or the wiring substrate 110). Among the plurality of bumps 180 of the first bonding portion 171, the remaining bumps 180 may be provided on the wiring substrate 110 (or the semiconductor chip 100).

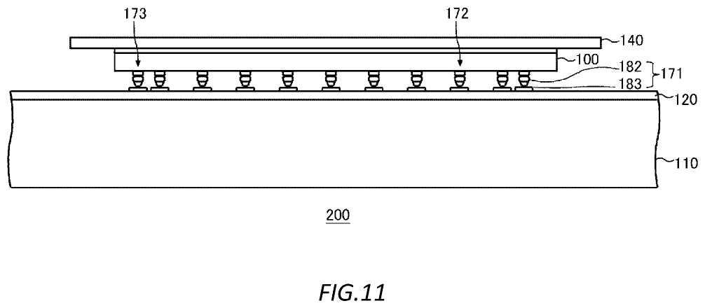

FIG. 11 is a diagram showing other examples of the first bonding portion 171, the second bonding portion 172, and the third bonding portion 173. The second bonding portion 172 and the third bonding portion 173 may have the same structure as that of the first bonding portion 171. Although not shown in FIG. 11, the fourth bonding portion 174, the fifth bonding portion 175, and the gate bonding portion 161 may also have the same structure as that of the first bonding portion 171.

At least one first bonding portion 171 has a pillar-shaped part 182 and a plate-shaped part 183. The pillar-shaped part 182 has the same structure as that of any of the first bonding portions 171 described with reference to FIG. 1 to FIG. 10. The pillar-shaped part 182 shown in FIG. 11 has the multi-stage bump structure described in FIG. 10.

The plate-shaped part 183 is stacked on the pillar-shaped part 182 in the connection direction. In the present example, the pillar-shaped part 182 is in contact with either the semiconductor chip 100 or the wiring substrate 110, and the plate-shaped part 183 is in contact with another of the semiconductor chip 100 and the wiring substrate 110. The plate-shaped part 183 is a part having a width greater than that of the pillar-shaped part 182 in the direction perpendicular to the connection direction. A thickness of the plate-shaped part 183 in the connection direction may be smaller than the length of the pillar-shaped part 182 in the connection direction. By providing the plate-shaped part 183, it is possible to increase a contact area between the first bonding portion 171 and the semiconductor chip 100 or the wiring substrate 110. Therefore, it is possible to reinforce the bonding strength between the first bonding portion 171 and the semiconductor chip 100 or the wiring substrate 110.

The plate-shaped part 183 may be formed of a material that has higher connectivity with the pillar-shaped part 182 than the main wiring 120. For example, the plate-shaped part 183 is formed of the same material as the pillar-shaped part 182. The main wiring 120 may be formed of a material different from that of the plate-shaped part 183. By performing the connection between the materials different from each other on the plate-shaped part 183 having a comparatively great area, it is likely that the bonding strength is reinforced. In another example, the plate-shaped part 183 may be formed of the same material as that of the main wiring 120.

In the example of FIG. 11, the second bonding portion 172 also has the pillar-shaped part 182 and the plate-shaped part 183. In another example, the second bonding portion 172 may have the pillar-shaped part 182 rather than the plate-shaped part 183. In this case, similar to the examples of FIG. 8 and FIG. 9, the length L1 of the first bonding portion 171 may be greater than the length L2 of the second bonding portion 172. The length of the pillar-shaped part 182 of the first bonding portion 171 may be the same as the length of the pillar-shaped part 182 of the second bonding portion 172. In this case, the length L1 of the first bonding portion 171 is longer than the length L2 of the second bonding portion 172, by the thickness of the plate-shaped part 183. In another example, similar to the example of FIG. 10, the length of the pillar-shaped part 182 of the first bonding portion 171 may be longer than the length of the pillar-shaped part 182 of the second bonding portion 172. The third bonding portion 173, the fourth bonding portion 174, the fifth bonding portion 175, and the gate bonding portion 161 may have structures similar to that of the first bonding portion 171.

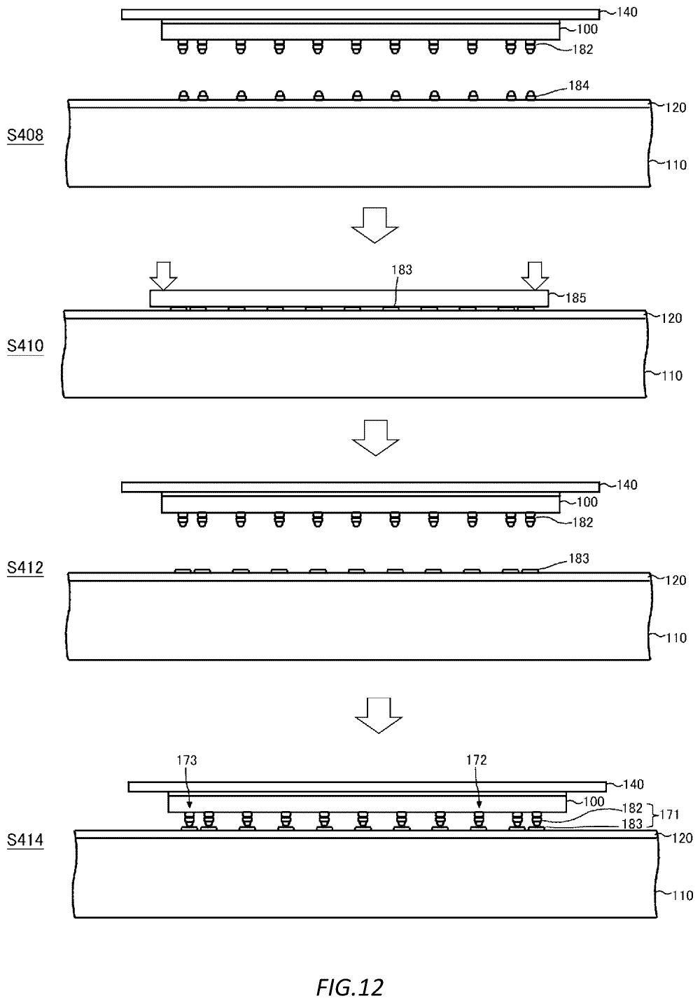

FIG. 12 is a diagram showing an example of a manufacturing step for the semiconductor module 200 shown in FIG. 11. Steps before step S408 shown in FIG. 12 are similar to steps S302 to S306 shown in FIG. 3.

In step S408, the pillar-shaped part 182 is provided on the semiconductor chip 100 (or the wiring substrate 110), and a pillar-shaped part 184 is provided on the wiring substrate 110 (or the semiconductor chip 100). The pillar-shaped part 184 may be shorter than the pillar-shaped part 182 in the connection direction.

In step S410, each of the pillar-shaped parts 184 is pressed to form a plate-shaped part 183. In step S410, a press member 185 having a flat surface may be used to collectively press a plurality of pillar-shaped part 184. This makes it possible to easily form the plate-shaped part 183 with a uniform thickness.

By step S408 and step S410, the pillar-shaped part 182 is provided on one of the main electrode 20 of the semiconductor chip 100 and the main wiring 120 of the wiring substrate 110. In addition, the plate-shaped part 183 is provided on another of the main electrode 20 and the main wiring 120.

In step S412, the semiconductor chip 100 and the wiring substrate 110 are aligned such that the pillar-shaped parts 182 are respectively connected to the plate-shaped parts 183. In step S414, the semiconductor chip 100 and the wiring substrate 110 are bonded together. By step S414, it is possible to connect the pillar-shaped part 182 to the plate-shaped part 183. This makes it possible to form each bonding portion, including at least one first bonding portion 171. By such a step, it is possible to easily manufacture the semiconductor module 200 shown in FIG. 11.

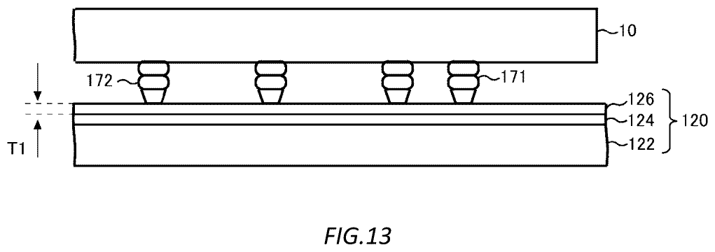

FIG. 13 is a diagram showing a structure example of the main wiring 120. FIG. 13 shows an enlarged view of a vicinity of the first bonding portion 171. The main wiring 120 of the present example has a base material portion 122, a nickel layer 124, and a gold plating layer 126. The base material portion 122 is a part formed of metal such as copper or aluminum.

The nickel layer 124 is formed on the base material portion 122. The nickel layer 124 may be a layer obtained by plating an upper surface of the base material portion 122 with nickel. In the connection direction, the nickel layer 124 may be thinner than the base material portion 122.

The gold plating layer 126 is formed on the nickel layer 124. The gold plating layer 126 may be a layer obtained by plating an upper surface of the nickel layer 124 with gold. In the connection direction, the gold plating layer 126 may be thinner than the base material portion 122.

The gold plating layer 126 is bonded to each of the main electrode bonding portions 170 (the first bonding portion 171 and the second bonding portion 172 in FIG. 13). The main electrode bonding portion 170 may be formed of gold. When nickel is exposed, onto the gold plating layer 126, in a part that is in contact with the main electrode bonding portion 170, the bonding strength between the gold plating layer 126 and the main electrode bonding portion 170 becomes weak. For this reason, it is preferable that no nickel is present, on the gold plating layer 126, on a surface that is bonded to the main electrode bonding portion 170. When the gold plating layer 126 is formed, nickel from the underlying nickel layer 124 may be deposited on a front surface of the gold plating layer 126. For example, when the gold plating layer 126 is thin, nickel is likely to be deposited. In addition, when the temperature at which the gold plating layer 126 is formed is high, nickel is likely to be deposited. In addition, when a time during which the gold plating layer 126 is formed is long, nickel is likely to be deposited. By adjusting these conditions, it is possible to suppress a deposition of nickel on the front surface of the gold plating layer 126. Nickel may be present, on the front surface of the gold plating layer 126, in a part that is not in contact with the main electrode bonding portion 170.

A thickness T1 of the gold plating layer 126 in the connection direction may be 0.5 μm or more. This makes it possible to suppress the deposition of nickel on the front surface of the gold plating layer 126. The thickness T1 may be 0.7 μm or more, or may be 1 μm or more. The thickness T1 may be 3 μm or less, may be 2 μm or less, or may be 1.5 μm or less. Even when the gold plating layer 126 is thin, by providing the plate-shaped part 183 on the front surface of the gold plating layer 126 as shown in FIG. 11, it is possible to suppress the deposition of nickel on the front surface of the plate-shaped part 183. In the present example, by causing the gold plating layer 126 to be thick, it is possible to suppress the deposition of nickel on the contact surface with the pillar-shaped part 182 without providing the plate-shaped part 183.

In the example of FIG. 13, the structure of the main wiring 120 is described; however, at least one of the main electrode 20 or the main wiring 120 may have the structure in which the gold plating layer 126, the nickel layer 124, and the base material portion 122 are stacked. The structure of the present example may be applied to any of the examples described in the present specification. In addition, in the example in which the thickness T1 of the gold plating layer 126 is 0.5 μm or more, the main electrode connection part 150 may have only the second region 152 rather than the first region 151, the third region 153, the fourth region 154, and the fifth region 155. Even in this case, by suppressing the deposition of nickel on the front surface of the gold plating layer 126, it is possible to reinforce the bonding strength of the entire main electrode connection part 150.

At least one of the main electrode 20 or the main wiring 120 may have a structure in which the gold plating layer 126, a palladium layer, the nickel layer 124, and the base material portion 122 are stacked. This structure may be applied to any of the examples described in the present specification. The palladium layer is sandwiched between the gold plating layer 126 and the nickel layer 124. The palladium layer may be formed by plating the front surface of the nickel layer 124 with palladium. By providing the palladium layer, it is possible to suppress the deposition of nickel, which is contained in the nickel layer 124, on the front surface of the gold plating layer 126. When the palladium layer is provided, the thickness of the gold plating layer 126 may be smaller than 0.5 μm. The thickness of the gold plating layer 126 may be 0.1 μm or less. The thickness of the gold plating layer 126 may be 0.01 μm or more.

The semiconductor module 200 described with reference to FIG. 1 to FIG. 13 can be manufactured by using steps similar to steps S302 to S312 in FIG. 3, and steps S408 to S414 in FIG. 12. It is to be noted that as in step S308 or step S408, in the step of providing the main electrode bonding portion 170 on the main electrode connection part 150, the first region 151 and the second region 152 are set for the main electrode connection part 150. In addition, the third region 153, the fourth region 154, and the fifth region 155 may be appropriately set for the main electrode connection part 150. As described above, the arrangement or the like of the main electrode bonding portions 170 in each region is adjusted such that the bonding strength per unit area by the first bonding portions 171 is higher than the bonding strength per unit area by the second bonding portions 172. The adjustment is similar to those in the examples described with reference to FIG. 1 to FIG. 13.

As shown in FIG. 13, in the step of manufacturing the semiconductor module 200 including the nickel layer 124 and the gold plating layer 126, the step from forming the nickel layer 124 and the gold plating layer 126 to connecting the first bonding portion 171 to the gold plating layer 126, may be performed at a temperature of 250° C. or less. This makes it possible to suppress the deposition of nickel, on the gold plating layer 126, in a part that is in contact with the first bonding portion 171. The connection step of connecting the first bonding portion 171 to the gold plating layer 126 refers to a step of connecting at least a part constituting the first bonding portion 171 to the gold plating layer 126.

For example, when the main wiring 120 is provided with the gold plating layer 126 and the nickel layer 124, and the main electrode 20 is provided with the first bonding portion 171 as shown in FIG. 3, the connection step is step S312 of connecting the first bonding portion 171 to the main wiring 120. In this case, the step from forming the nickel layer 124 and the gold plating layer 126 to an end of step S312 may be performed at a temperature of 250° C. or less. In addition, when the main wiring 120 is provided with the gold plating layer 126 and the nickel layer 124, and the main wiring 120 is provided with the plate-shaped part 183 which is a part of the first bonding portion 171 as shown in step S410 of FIG. 12, the connection step is step S410 of forming the plate-shaped part 183 on the main wiring 120. In this case, the step from forming the nickel layer 124 and the gold plating layer 126 to an end of step S410 may be performed at a temperature of 250° C. or less.

When at least a part of the first bonding portion 171 is formed on the gold plating layer 126, nickel is less likely to be deposited, from the nickel layer 124, on a region covered with the first bonding portion 171. Therefore, by setting the temperature in the above step to 250° C. or less, it is possible to suppress the deposition of nickel, on the gold plating layer 126, on the front surface that is in contact with the first bonding portion 171. The temperature may be 230° C. or less, or may be 200° C. or less.

The step from forming the nickel layer 124 and the gold plating layer 126 to fixing the semiconductor chip 100 to the wiring substrate 110, may be performed at a temperature of 250° C. or less. The fixing step of fixing the semiconductor chip 100 to the wiring substrate 110 is a step of fixing the semiconductor chip 100 to the wiring substrate 110 by the main electrode bonding portion 170 and the gate bonding portion 161. In the example of FIG. 3, step S312 corresponds to the fixing step, and in the example of FIG. 12, step S414 corresponds to the fixing step. The step from forming the nickel layer 124 and the gold plating layer 126 to an end of the fixing step may be performed at a temperature of 250° C. or less. The temperature may be 230° C. or less, or may be 200° C. or less. By such a manufacturing step, it is possible to further suppress the deposition of nickel, on the gold plating layer 126, on the front surface that is in contact with the first bonding portion 171. In addition, in any of the examples, the step of forming the gold plating layer 126, as well, may be performed at 250° C. or less. The temperature may also be 230° C. or less, or may be 200° C. or less.

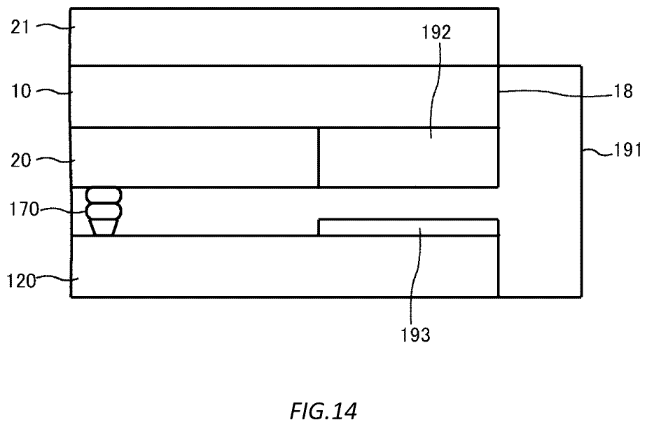

FIG. 14 is an enlarged cross-sectional view of a vicinity of an end side 18 of the semiconductor substrate 10. The end side 18 is any of the first end side 11, the second end side 12, the third end side 13, and the fourth end side 14. On the semiconductor substrate 10, the main electrode 20, a main electrode 21, and an interlayer dielectric film 192 are formed. The main electrode 20 and the main electrode 21 are, for example, an emitter electrode and a collector electrode in the IGBT.

The main electrode 20 is formed, on a predetermined surface of the semiconductor substrate 10, in a region in which the interlayer dielectric film 192 is not provided. The main electrode 21 may be formed on the entire surface of the semiconductor substrate 10 on an opposite side of the main electrode 20.

The interlayer dielectric film 192 of the present example is formed in a region that is in contact with the end side of the semiconductor substrate 10. In addition, the semiconductor chip 100 and the wiring substrate 110 are covered with a sealant 191 such as gel or epoxy resin. The sealant 191 is also injected into a region between the semiconductor substrate 10 and the main wiring 120.

The potential of the end side 18 of the semiconductor substrate 10 is approximately the same as the potential of the main electrode 21. In addition, the potential of the main wiring 120 is approximately the same as the potential of the main electrode 20. A difference in potential between the main electrode 20 and the main electrode 21 may be several hundred to several thousand volts. For this reason, it is preferable that the insulation between a vicinity of the end side 18, and the main wiring 120 is high.

In the semiconductor module 200 of the present example, a protective film 193 is provided between the interlayer dielectric film 192 and the main wiring 120. The protective film 193 is formed of a material having a higher electrical insulation property than that of the sealant 191. The protective film 193 is, for example, a polyimide film. By replacing, with the protective film 193, at least a part of the sealant 191 between the vicinity of the end side 18, and the main wiring 120, it is possible to enhance the insulation between the vicinity of the end side 18, and the main wiring 120. The protective film 193 of the present example is provided to be in contact with the main wiring 120, but may be provided to be in contact with the interlayer dielectric film 192.

On the other hand, the bonding strength of the main electrode bonding portion 170 in a vicinity of the protective film 193 may become weak due to the protective film 193 being provided. For example, in a case where the material of the protective film 193 (for example, polyimide) is present in the contact part between the main electrode bonding portion 170, and the main wiring 120 or the main electrode 20, the bonding strength becomes weak. In contrast with this, with the semiconductor module 200 described with reference to FIG. 1 to FIG. 13, it is possible to reinforce the bonding strength of the main electrode bonding portion 170 in the vicinity of the end side 18. This makes it possible, in both ways, to enhance the insulation between the vicinity of the end side 18, and the main wiring 120, and to maintain or enhance the bonding strength.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the description of the claims that the form to which such alterations or improvements are made can be included in the technical scope of the present invention.

What is claimed is:

1. A semiconductor module comprising:
a semiconductor chip having a gate pad and a main electrode which are provided on a same main surface;
a wiring substrate; and
a main electrode connection part which connects the main electrode of the semiconductor chip to the wiring substrate, wherein
a plurality of end sides in an outer shape of the semiconductor chip include a first end side that is closest to the gate pad, in a top view,
on an arrangement surface parallel to the main surface, the main electrode connection part has
a first region which is provided with a plurality of first bonding portions, and
a second region to which a distance from the first end side is greater than that to the first region, and which is provided with a plurality of second bonding portions, and
a bonding strength per unit area by the plurality of first bonding portions is higher than the bonding strength per unit area by the plurality of second bonding portions.

2. The semiconductor module according to claim 1, wherein
the first region has a recess portion which is recessed in a direction perpendicular to the first end side, and
the gate pad is arranged to face the recess portion.

3. The semiconductor module according to claim 1, further comprising:
a gate connection part including a plurality of gate bonding portions which connects the gate pad to the wiring substrate.

4. The semiconductor module according to claim 3, wherein
the bonding strength per unit area by the plurality of gate bonding portions is the same as the bonding strength per unit area by the plurality of first bonding portions.

5. The semiconductor module according to claim 3, wherein
the bonding strength per unit area by the plurality of gate bonding portions is smaller than the bonding strength per unit area by the plurality of first bonding portions.

6. The semiconductor module according to claim 2, wherein
the plurality of end sides of the semiconductor chip include a second end side that is farthest away from the first end side, and
the second region is provided up to a position that is closest to the second end side in the main electrode connection part.

7. The semiconductor module according to claim 2, wherein
the plurality of end sides of the semiconductor chip include a second end side that is farthest away from the first end side, and
on the arrangement surface parallel to the main surface, the main electrode connection part has a third region to which a distance from the second end side is smaller than that to the second region, and which includes a plurality of third bonding portions, and
the bonding strength per unit area by the plurality of third bonding portions is higher than the bonding strength per unit area by the plurality of second bonding portions.

8. The semiconductor module according to claim 1, wherein
a number of the plurality of first bonding portions per unit area is greater than a number of the plurality of second bonding portions per unit area.

9. The semiconductor module according to claim 1, wherein
at least one of the first bonding portions is longer than any of the second bonding portions in a connection direction connecting the main surface to the wiring substrate.

10. The semiconductor module according to claim 9, wherein
in each of the plurality of first bonding portions and each of the plurality of second bonding portions, one or more bumps are stacked in the connection direction, and
a number of stages of the bumps in at least one of the first bonding portions is greater than a number of stages of the bumps in any of the second bonding portions.

11. The semiconductor module according to claim 1, wherein
at least one of the first bonding portions includes
a pillar-shaped part, and
a plate-shaped part which is stacked on the pillar-shaped part in a connection direction connecting the main surface to the wiring substrate, and which has a width greater than that of the pillar-shaped part.

12. The semiconductor module according to claim 1, wherein
at least one of the main electrode or the wiring substrate has a gold plating layer which has a thickness of 0.5 μm or more, and which is bonded to at least one of the plurality of first bonding portions.

13. The semiconductor module according to claim 1, wherein
at least one of the main electrode or the wiring substrate has a gold plating layer arranged in a region that is bonded to at least one of the plurality of first bonding portions, and a nickel layer arranged below the gold plating layer, and
no nickel is present, on the gold plating layer, on a surface that is bonded to at least one of the plurality of first bonding portions.

14. The semiconductor module according to claim 2, wherein
at least one of the first bonding portions includes
a pillar-shaped part, and
a plate-shaped part which is stacked on the pillar-shaped part in a connection direction connecting the main surface to the wiring substrate, and which has a width greater than that of the pillar-shaped part.

15. The semiconductor module according to claim 3, wherein
at least one of the first bonding portions includes
a pillar-shaped part, and
a plate-shaped part which is stacked on the pillar-shaped part in a connection direction connecting the main surface to the wiring substrate, and which has a width greater than that of the pillar-shaped part.

16. The semiconductor module according to claim 4, wherein
at least one of the first bonding portions includes
a pillar-shaped part, and
a plate-shaped part which is stacked on the pillar-shaped part in a connection direction connecting the main surface to the wiring substrate, and which has a width greater than that of the pillar-shaped part.

17. A manufacturing method for a semiconductor module including: a semiconductor chip having a gate pad and a main electrode which are provided on a same main surface; a wiring substrate; and a main electrode connection part which connects the main electrode of the semiconductor chip to the wiring substrate, the manufacturing method comprising:
providing, in the main electrode connection part on an arrangement surface parallel to the main surface,
a first region which is provided with a plurality of first bonding portions, and
a second region to which a distance from the gate pad is greater than that to the first region, and which is provided with a plurality of second bonding portions, and
causing a bonding strength per unit area by the plurality of first bonding portions to be higher than the bonding strength per unit area by the plurality of second bonding portions.

18. The manufacturing method according to claim 17, further comprising:
by providing a pillar-shaped part on one of the main electrode and the wiring substrate,
by providing a plate-shaped part having a width greater than that of the pillar-shaped part, on another of the main electrode and the wiring substrate, and
by connecting the pillar-shaped part to the plate-shaped part, forming at least one of the first bonding portions.

19. The manufacturing method according to claim 17, wherein
at least one of the main electrode or the wiring substrate has a gold plating layer arranged in a region that is bonded to the first region of the main electrode connection part, and a nickel layer arranged below the gold plating layer, and
from forming the nickel layer and the gold plating layer, to forming at least a part of the plurality of first bonding portions on the gold plating layer, a performance temperature is 250° C. or less.

20. The manufacturing method according to claim 19, wherein
from forming the nickel layer and the gold plating layer, to fixing the semiconductor chip to the wiring substrate, a performance temperature is 250° C. or less.
